(19) United States
(12) Patent Application Publication
(10) Pub. No.: US 2008/0100763 A1
(43) Pub. Date: May 1, 2008

(54) CIRCUIT BOARD AND DISPLAY DEVICE HAVING THE SAME

(76) Inventor: Jong-kook Park, Cheonan-si (KR)

Correspondence Address: F. CHAU & ASSOCIATES, LLC, 130 WOODBURY ROAD, WOODBURY, NY, 11797, US

(21) Appl. No.: 11/923,182

(22) Filed: Oct. 24, 2007

(30) Foreign Application Priority Data
Nov. 1, 2006 (KR) 10-2006-0107330

(51) Int. Cl. G02F 1/136; H05K 1/00

(52) U.S. Cl. 349/42; 174/250

(57) ABSTRACT

A circuit board outputs a plurality of signals through first to n-th connection portions. Each of the connection portions includes a ground pad, signal output pads outputting the signals, and conductive dummy pads insulated from the ground pad and the signal output pads. The plurality of signals include gate driving signals and data driving signals.

### CROSS REFERENCE TO RELATED APPLICATION

This application claims priority to Korean Patent Application No. 10-2006-0107330 filed on Nov. 1, 2006, the disclosure of which is incorporated herein by reference in its entirety.

### BACKGROUND OF THE INVENTION

1. Technical Field

The present invention relates to a circuit board and a display device having the same, and more particularly to a circuit board capable of improving prevention of electrostatic discharge (hereinafter, referred to as “ESD”).

2. Discussion of the Related Art

A liquid crystal display (LCD) device is one type of display device. The LCD device includes a liquid crystal panel assembly to display an image and a backlight assembly to provide light to the liquid crystal panel assembly. Power lines to provide a power supply voltage and various signal lines are connected in a complex manner in the LCD device. As a result, an overvoltage or an overcurrent can occur due to ESD that flows from the outside and is transferred to the LCD device through the power lines or the signal lines.

Since the liquid crystal panel assembly includes a liquid crystal panel, and data driving semiconductor chip packages to supply data signals to the liquid crystal panel, the ESD that flows from the outside is transferred to the LCD device through the liquid crystal panel. That is, the ESD is transferred to the data driving semiconductor chip packages through the liquid crystal panel. Further, since the data driving semiconductor chip packages are connected to a timing controller and a circuit board, on which a plurality of circuits are mounted, the ESD transferred to the data driving semiconductor chip packages may be transferred to the circuit board, and thus the timing controller and the plurality of circuits may be damaged.

Thus, the timing controller and the plurality of circuits may erroneously operate, causing display quality to be degraded.

### SUMMARY OF THE INVENTION

Embodiments of the present invention provide a circuit board capable of increased prevention of ESD, and a display device having the circuit board.

According to an exemplary embodiment of the present invention, there is provided a circuit board, the circuit board including first to n-th connection portions to supply a plurality of signals, wherein each of the connection portions comprises a ground pad, signal output pads to output the signals; and conductive dummy pads insulated from the ground pad and the signal output pads.

According to an exemplary embodiment of the present invention, there is provided a display device, the display device including a circuit board to output a plurality of signals through first to n-th connection portions, each of the connection portions including a ground pad, signal output pads outputting the signals, and conductive first dummy pads insulated from the ground pad and the signal output pads, first to n-th data driving semiconductor chip packages connected to the first to n-th connection portions, a plurality of gate driving semiconductor chip packages connected to the circuit board, and a liquid crystal panel including a plurality of data lines connected to the first to n-th data driving semiconductor chip packages, a plurality of gate lines electrically connected to the plurality of gate driving semiconductor chip packages, and second dummy pads connected to the first to n-th data driving semiconductor chip packages.

### BRIEF DESCRIPTION OF THE DRAWINGS

Exemplary embodiments of the present invention can be understood in more detail from the following descriptions taken in conjunction with the accompanying drawings, in which:

FIG. 1 is an exploded perspective view illustrating a liquid crystal display according to an exemplary embodiment of the present invention;

FIG. 2A is a perspective view illustrating a circuit board according to an exemplary embodiment of the present invention;

FIG. 2B is a perspective view illustrating a first data driving semiconductor chip package of FIG. 2A;

FIG. 2C is a perspective view illustrating second to n-th data driving semiconductor chip packages of FIG. 2A;

FIG. 2D is a perspective view illustrating a liquid crystal panel of FIG. 1;

FIG. 3 is an exploded perspective view illustrating a liquid crystal display according to an exemplary embodiment of the present invention;

FIG. 4 is a perspective view illustrating a liquid crystal panel assembly of FIG. 3;

FIG. 5 is an exploded perspective view illustrating a display device according to an exemplary embodiment of the present invention;

FIG. 6A is a perspective view illustrating a circuit board according to an exemplary embodiment of the present invention;

FIG. 6B is a perspective view illustrating a liquid crystal panel of FIG. 5;

FIG. 7A is a perspective view illustrating a circuit board according to an exemplary embodiment of the present invention;

FIG. 7B is a perspective view illustrating first to n-th data driving semiconductor chip packages of FIG. 7A;

FIG. 7C is a perspective view illustrating second to (n−1)th data driving semiconductor chip packages of FIG. 7A; and

FIG. 7D is a perspective view illustrating a liquid crystal panel according to an exemplary embodiment of the present invention.

### DESCRIPTION OF THE EXEMPLARY EMBODIMENTS

Exemplary embodiments of the present invention are described more fully hereinafter with reference to the accompanying drawings, in which exemplary embodiments of the invention are shown. This invention may, however, be embodied in many different forms and should not be construed as limited to the embodiments set forth herein. Like reference numerals may refer to like elements throughout the specification.

Examples of semiconductor chip packages include tape carrier packages (hereinafter, referred to as “TCP”), or COF (Chip On Film) or COG (Chip On Glass). In the following description, data driving semiconductor chip packages and gate driving semiconductor chip packages represent one of the TCP, COF, and COG. Further, the present invention will be described by way of a liquid crystal display as an example of a display device. However, the present invention is not limited to the liquid crystal display. In addition, the number of signal output pads, ground pads, first dummy pads, or second dummy pads, and the arrangement sequence are not limited to those shown in the drawings.

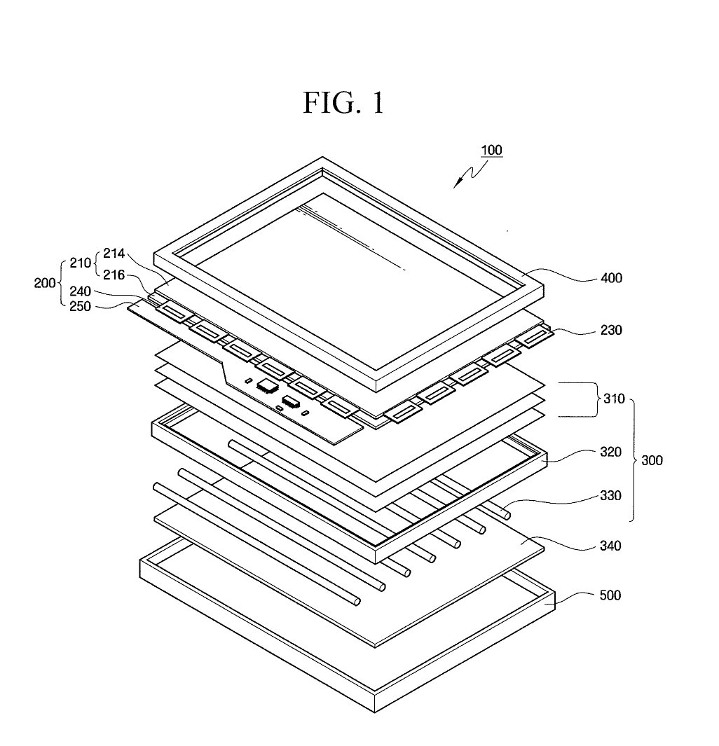

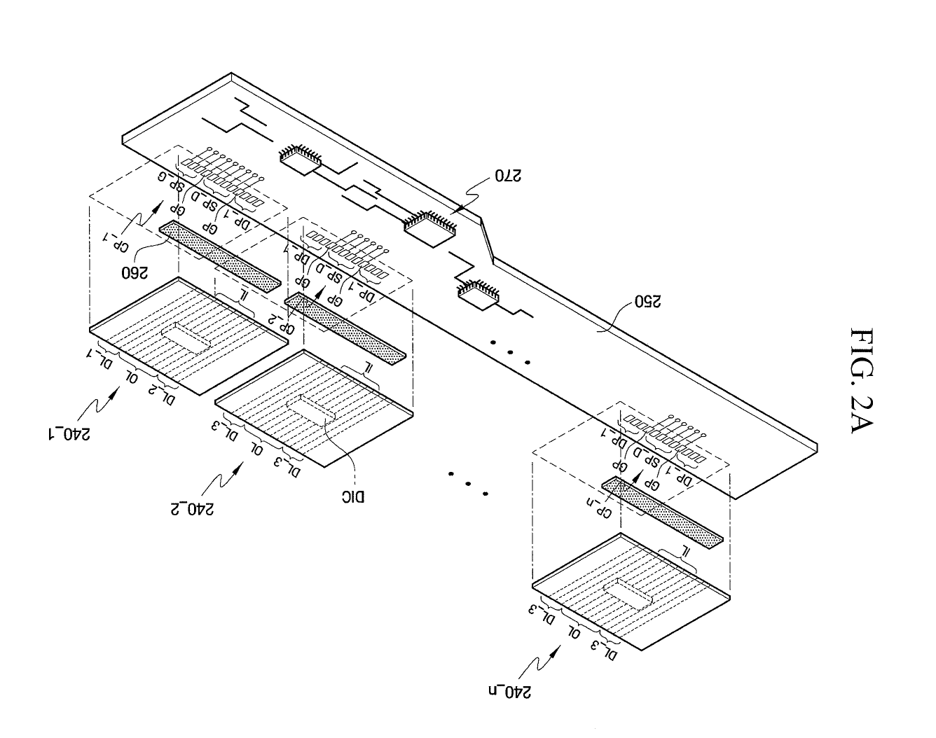

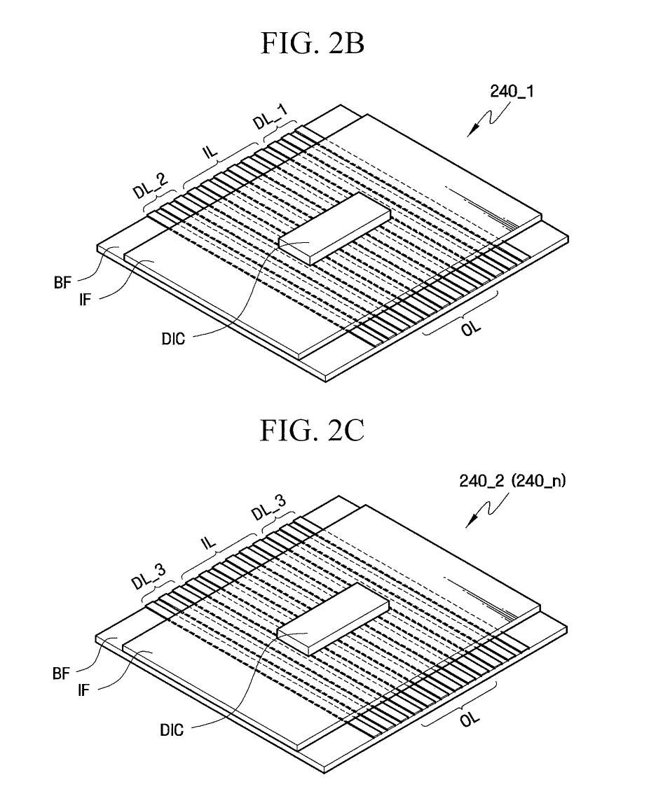

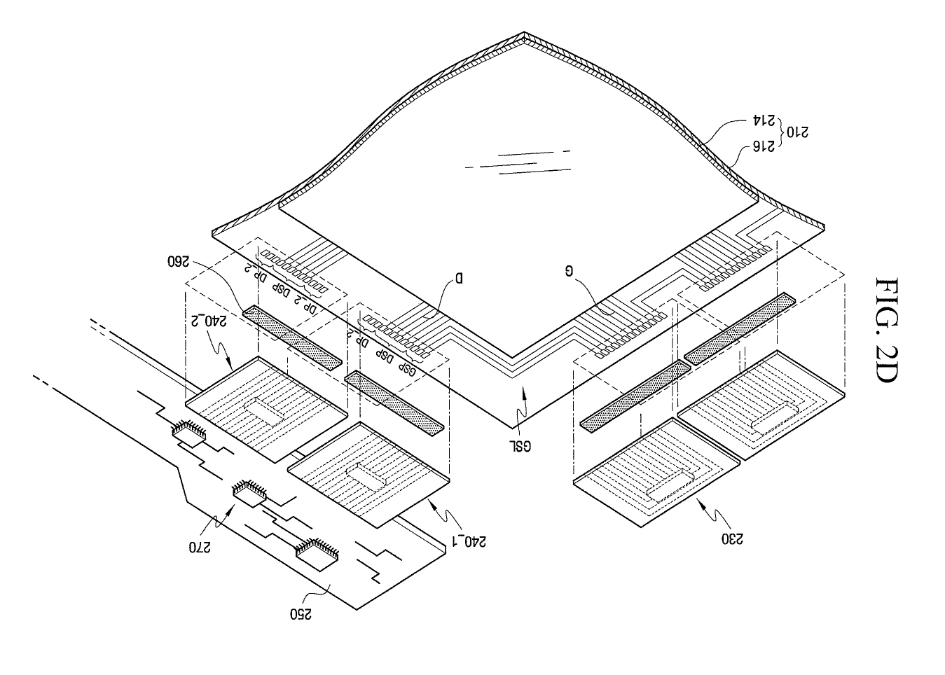

FIG. 1 is an exploded perspective view illustrating a liquid crystal display according to an exemplary embodiment of the present invention. FIG. 2A is a perspective view illustrating a circuit board according to an embodiment of the present invention. FIG. 2B is a perspective view illustrating a first data driving semiconductor chip package of FIG. 2A. FIG. 2C is a perspective view illustrating second to n-th data driving semiconductor chip packages of FIG. 2A. FIG. 2D is a perspective view illustrating a liquid crystal panel of FIG. 1.

Referring to FIG. 1, a liquid crystal display (LCD) device 100 may include a liquid crystal panel assembly 200, a backlight assembly 300, an upper case 400, and a lower case 500.

The liquid crystal panel assembly 200 includes a liquid crystal panel 210, a plurality of gate driving semiconductor chip packages 230, a plurality of data driving semiconductor chip packages 240, and a circuit board 250.

The liquid crystal panel 210 includes a first substrate 216 on which thin film transistors and pixel electrodes are formed, a second substrate 214 on which color filters and a common electrode are formed, and a liquid crystal layer (not shown) interposed between the first substrate 216 and the second substrate 214.

In the circuit board 250, a timing controller and a plurality of circuit elements 270 that supply gate driving signals to be supplied to a plurality of gate driving semiconductor chip packages 230 and data driving signals to be supplied to a plurality of data driving semiconductor chip packages 240 are integrated. The circuit board 250 may be a printed circuit board.

The backlight assembly 300 includes optical sheets 310, a mold frame 320, a lamp unit 330, and a reflecting plate 340.

The optical sheets 310 are positioned over the lamp unit 330 to diffuse and focus light emitted from the lamp unit 330. The optical sheets 310 include a diffusion sheet, a prism sheet, and/or a protective sheet.

The mold frame 320 supports and fixes the optical sheets 310, the lamp unit 330, and the reflecting plate 340.

The lamp unit 330 may be a direct type in which a plurality of lamps are provided in parallel with each other. The lamp unit 330 may be an edge type. In the edge type, a light guide plate (not shown) to disperse light may be included.

The reflecting plate 340 is positioned behind the lamp unit 330 to reflect light emitted from the lamp unit 330 to be directed toward the liquid crystal panel assembly 200. The reflecting plate 330 may be integrally formed with the bottom of the lower case 500.

Referring to FIG. 2A, the circuit board 250 includes first to n-th connection portions CP_1 to CP_n, and are electrically connected to n data driving semiconductor chip packages 240_1 to 240_n through the connection portions CP_1 to CP_n, respectively.

Each of the connection portions CP_1 to CP_n includes a ground pad GP, signal output pads SP_D and SP_G, and first dummy pads DP_1.

A ground voltage of the circuit board 250 is applied to the ground pad GP. In other words, to the ground pad GP, the ground voltage to be commonly supplied to the timing controller and the plurality of circuit elements 270 mounted on the circuit board 250 is applied.

The signal output pads SP_D and SP_G output the data driving signals or the gate driving signals to be supplied from the timing controller and the plurality of circuit elements 270 mounted on the circuit board 250.

The first dummy pads DP_1 are electrically insulated from the ground pad GP and the signal output pads SP_D and SP_G. The first dummy pads DP_1 are formed adjacent to and in parallel with the ground pad GP and the signal output pads SP_D and SP_G.

Referring to FIGS. 2A and 2C, the first connection portion CP_1 includes the ground pad GP, the signal output pads SP_D and SP_G. and the first dummy pads DP_1. The signal output pads SP_D and SP_G includes data signal output pads SP_D that output image signals and data driving signals, and gate signal output pads SP_G that output gate driving signals. The gate signal output pads SP_G may be formed on a side of the circuit board 250, as shown in FIG. 2A.

The first data driving semiconductor chip package 240_1 connected to the first connection portion CP_1 includes an insulating base film BF, a data driving IC DIC, data signal input lines IL, gate signal output lines DL_1, dummy lines DL_2, data signal output lines OL, and an insulating protective film IF as shown in FIG. 2B.

Particularly, the data signal input lines IL are electrically connected to the ground pad GP and the data signal output pads SP_D, and the data driving IC DIC. The data signal input lines IL supply the ground voltage, the image signals, and the data driving signals output through the ground pad GP and the data signal output pads SP_D to the data driving IC DIC.

The gate signal output lines DL_1 are electrically connected to the gate signal output pads SP_G and the gate driving semiconductor chip package 230. The gate signal output lines DL_1 supply the gate driving signals to the gate driving semiconductor chip package 230.

The dummy lines DL_2 are connected to the first dummy pads DP_1 and second dummy pads DP_2 on the liquid crystal panel 210, and the data signal output lines OL are electrically connected to the data driving IC DIC and a plurality of data lines D on the liquid crystal panel 210.

The data signal input lines IL, the gate signal output lines DL_1, the dummy lines DL_2, and the data signal output lines OL are formed on the base film BF to have a thickness in a range of from about 5 μm to about 20 μm, and include a metal material, such as a copper foil (Cu). For example, plating of tin, gold, nickel, or solder may be performed on the surface of the copper foil. The base film BF may include an insulating material having a thickness in a range of from about 20 μm to about 100 μm. The insulating base film BF may include an insulating material, such as polyimide resin, and/or polyester resin.

The insulating protective film IF covers the data signal input lines IL, the gate signal output lines DL_1, the dummy lines DL_2, and the data signal output lines OL, excluding a predetermined portion where the data driving IC DIC is mounted, to protect the lines.

The first data driving semiconductor chip package 240_1 is adhered to the first connection portion CP_1 through an anisotropic conductive film 260.

The first dummy pads DP_1 are electrically insulated from the ground pad GP and the signal output pads SP_D and SP_G. The first dummy pads DP_1 are electrically insulated from the timing controller and the circuit elements 270 mounted on the circuit board 250. Thus, when ESD flows along the liquid crystal panel 210 and flows into the circuit board 250 along the dummy lines DL_2, the ESD is not transferred to the timing controller and the circuit elements 270.

The second and n-th connection portions CP_2 to CP_n are correspondingly coupled to the second to n-th data driving semiconductor chip packages 240_2 to 240_n through the anisotropic conductive film 260.

Each of the second to n-th connection portions CP_2 to CP_n includes signal output pads SP_D, a ground pad GP, and first dummy pads DP_1. The first dummy pads DP_1 are electrically insulated from the signal output pads SP_D and the ground pad GP, and the signal output pads SP_D to output only the data driving signals.

Each of the second to n-th data driving semiconductor chip packages 240_2 to 240_n include data signal input lines IL, dummy lines DL_3, and data signal output lines OL as shown in FIG. 2C.

Particularly, the data signal input lines IL are electrically connected to the signal output pads SP_D and the data driving IC DIC, and the dummy lines DL_3 electrically connected to the first dummy pads DP_1 and the second dummy pads DP_2 on the liquid crystal panel 210. Further, the data signal output lines OL are electrically connected to the data driving IC DIC and a plurality of data lines D as shown in FIG. 2D.

The first dummy pads DP_1 are electrically insulated from the ground pad GP and the signal output pads SP_D. Thus, when ESD flows along the liquid crystal panel 210 and flows into the circuit board 250 along the dummy lines DL_2, the ESD is not transferred to the timing controller and the circuit elements 270.

The data driving semiconductor chip packages 240_2 to 240_n and the gate driving semiconductor chip packages 230 are coupled to the liquid crystal panel 210 through the anisotropic conductive film 260 as shown in FIG. 2D.

The liquid crystal panel 210 includes gate signal input pads GSP, data signal input pads DSP, and second dummy pads DP_2 for connection to the data driving semiconductor chip packages 240_2 to 240_n. Further, the liquid crystal panel 210 may further include gate signal transmission lines GSL to transmit gate signals.

Particularly, for the connection to the first data driving semiconductor chip package 240_1, the gate signal input pads GSP, the data signal input pads DSP, and the second dummy pads DP_2 are formed in a region on the liquid crystal panel 210 facing the first data driving semiconductor chip package 240_1.

The gate signal input pads GSP are connected to the gate signal output lines DL_1 of the first data driving semiconductor chip package 240_1. The gate signal input pads GSP receive the gate signals output from the gate signal output pads SP_G on the circuit board 250 through the gate signal output lines DL_1. The input gate signals are transmitted to the gate driving semiconductor chip packages 230 through the gate signal transmission lines GSL. The gate driving semiconductor chip packages 230 are electrically connected to a plurality of gate lines G.

The data signal input pads DSP are connected to the data signal output lines OL. Further, the data signal input pads DSP are electrically connected to the data lines D.

The second dummy pads DP_2 are connected to the first data driving semiconductor chip package 240_1 and die liquid crystal panel 210. The second dummy pads DP_2 are adhered to the dummy lines DL_2 of the first data driving semiconductor chip package 240_1 through the anisotropic conductive film 260. The second dummy pads DP_2 are insulated from the data lines D.

The second dummy pads DP_2 and the data signal input pads DSP are formed in a region on the crystal panel 210 facing the second data driving semiconductor chip package 240_2 for the connection to the second data driving semiconductor chip package 240_2.

The data signal input pads DSP are connected to the data signal output lines OL, and the data signal input pads DSP are electrically connected to the data lines D.

The second dummy pads DP_2 are adhered to the dummy lines DL_3 of the second data driving semiconductor chip package 240_2 through the anisotropic conductive film 260, and are connected to the second data driving semiconductor chip package 240_2 and the liquid crystal panel 210. The second dummy pads DP_2 are insulated from the data lines D.

ESD may flow into the first dummy pads DP_1 on the circuit board 250 through the liquid crystal panel 210, the second dummy pads DP_2, and the dummy lines DL_2 and DL_3. However, the first dummy pads DP_1 are insulated from the ground pad GP and the signal output pads GP_D and GP_G. The first dummy pads DP_1 are electrically insulated from the timing controller and the plurality of circuit elements 270 mounted on the circuit board 250.

Thus, when ESD flows into the first dummy pads DP_1 along the liquid crystal panel 210, the second dummy pads DP_2, and the dummy lines DL_2 and DL_3, ESD is not transferred to the timing controller and the plurality of circuit elements 270. Therefore, the timing controller and the plurality of circuit elements 270, and the LCD device 100 can be protected from ESD.

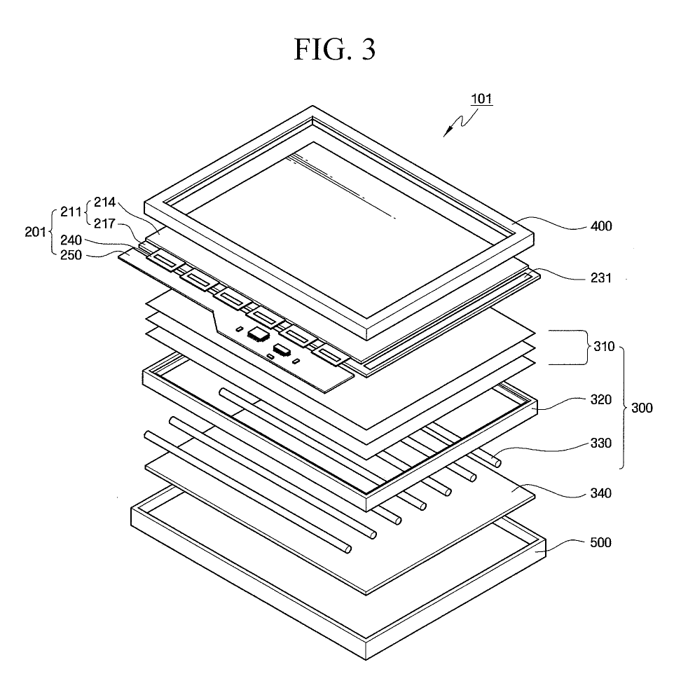

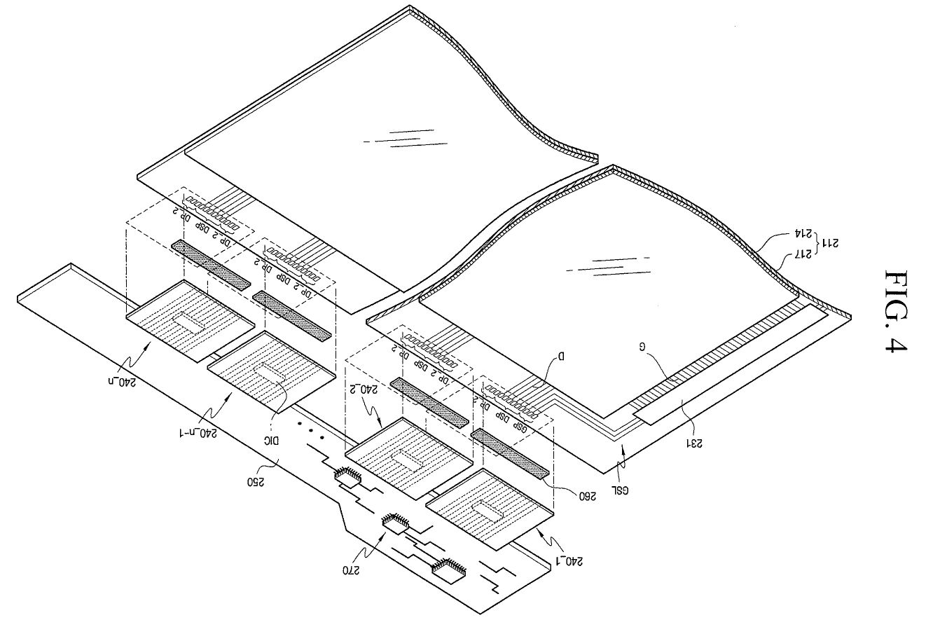

FIG. 3 is an exploded perspective view illustrating an LCD device according to an exemplary embodiment of the present invention. FIG. 4 is a perspective view illustrating a liquid crystal panel assembly of FIG. 3. Parts having the same functions as those shown in FIGS. 1 and 2D are represented by the same reference numerals, and the detailed descriptions thereof will be omitted for convenience of explanation.

Referring to FIGS. 3 and 4, the gate driving semiconductor chip packages 231 are mounted on the first substrate 217 of the liquid crystal panel 211. The gate driving semiconductor chip packages 231 are mounted on the first substrate 217 using a COG method.

The gate driving semiconductor chip packages 231 are mounted on only one side of the first substrate 217 of the liquid crystal panel 211, and are electrically connected to the gate signal transmission lines GSL and the gate lines G.

The first to n-th data driving semiconductor chip packages 240_1 240_n and the circuit board 250 are the same as the first to n-th data driving semiconductor chip packages and the circuit board in the embodiment described with reference to FIGS. 2A to 2D.

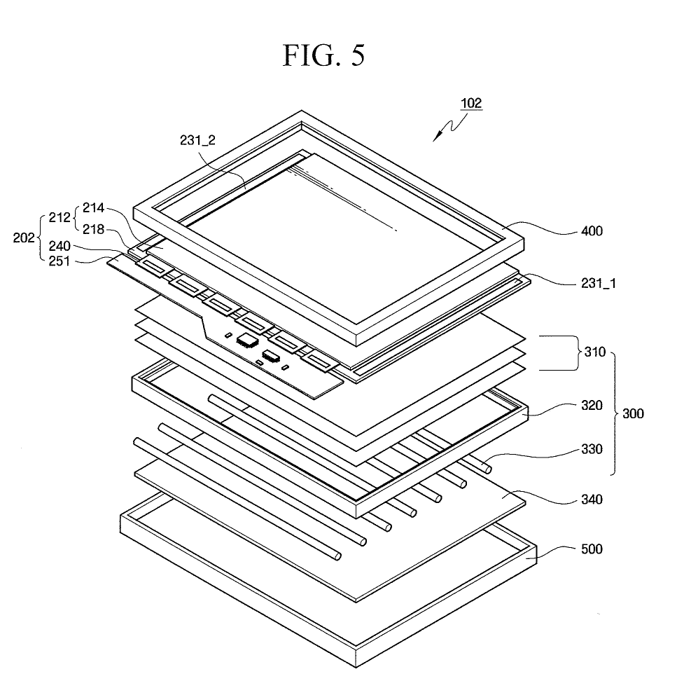

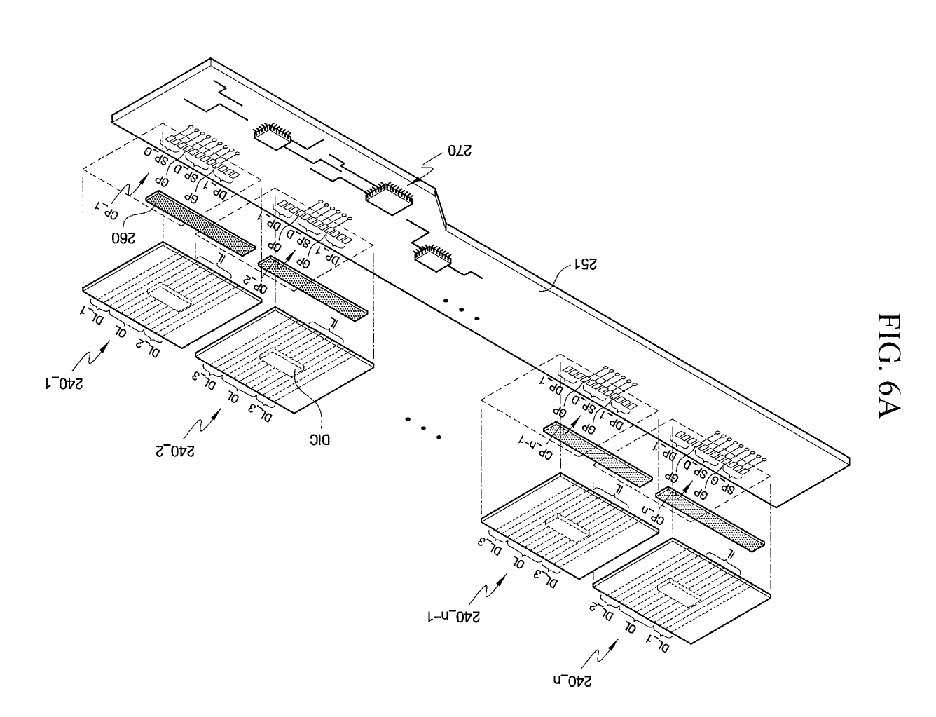

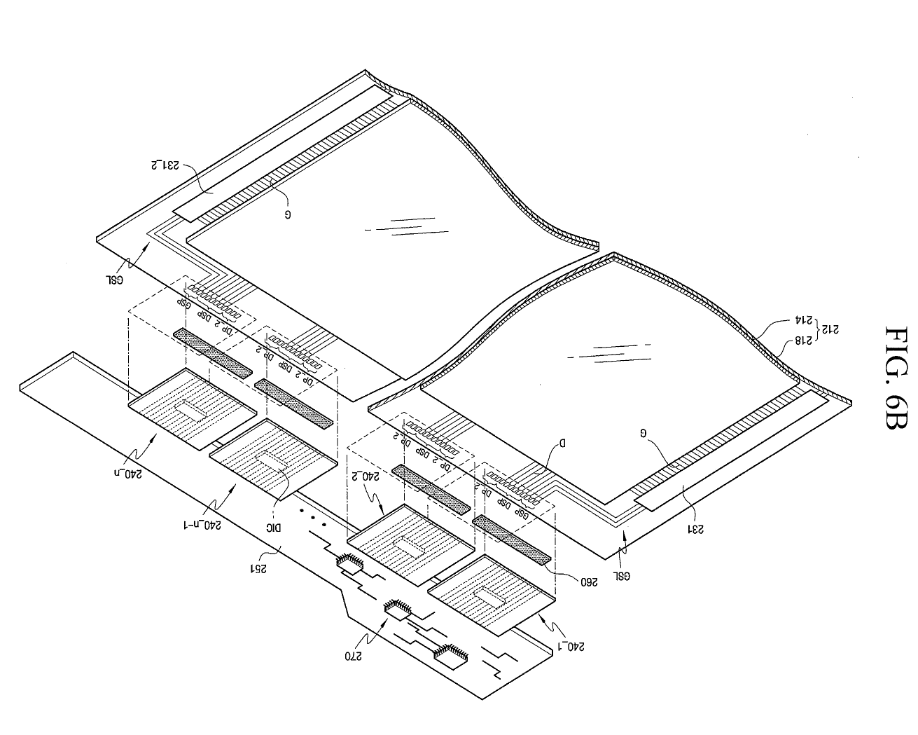

FIG. 5 is an exploded perspective view illustrating a display device according to an exemplary embodiment of the present invention. FIG. 6A is a perspective view illustrating a circuit board according to an exemplary embodiment of the present invention. FIG. 6B is a perspective view illustrating a liquid crystal panel of FIG. 5. Parts having the same functions as those shown in FIGS. 1 and FIGS. 2A to FIG. 2D are represented by the same reference numerals, and the detailed descriptions thereof will be omitted for convenience of explanation.

Referring to FIG. 5, the gate driving semiconductor chip packages are divided into a group of first gate driving semiconductor chip packages 231_1 and a group of second gate driving semiconductor chip packages 231_2, and are mounted on the first substrate 218 of the liquid crystal panel 212 using a COG method.

Referring to FIG. 6A, the circuit board 251 includes first to n-th connection portions CP_1 to CP_n. The n-th connection portion CP_n includes gate signal output pads SP_G, data signal output pads SP_D, and first dummy pads DP_1, like the first connection portion CP_1.

The n-th data driving semiconductor chip package 240_n includes data signal input lines IL, data signal output lines OL, gate signal output lines DL_1, and dummy lines DL_2. The gate signal output lines DL_1 are connected to the gate signal output pads SP_G, and the dummy lines DL_2 are connected to the first dummy pads DP_1.

Referring to FIG. 6B, gate signal input pads GSP, data signal input pads DSP, and second dummy pads DP_2 are formed in a region on the liquid crystal panel 212 facing the n-th data driving semiconductor chip package 240_n.

The group of first gate driving semiconductor chip packages 231_1 and the group of second gate driving semiconductor chip packages 231_2 receive the gate signals transmitted from the gate signal input pads GSP through the gate signal transmission lines GSL.

The second to (n−1)th data driving semiconductor chip packages 240_2 to 240_n are electrically connected to the data signal input pads DSP and the second dummy pads DP_2.

The first dummy pads DP_1 of the circuit board 251 are electrically insulated from the ground pad GP and the signal output pads SP_D and SP_G. The first dummy pads DP_1 are electrically insulated from the timing controller and the plurality of circuit elements 270 mounted on the circuit board 250.

Thus, when ESD flows into the first dummy pad DP_1 along the liquid crystal panel 210, the second dummy pads DP_2, and the dummy lines DL_2 and DL_3, ESD is not transferred to the timing controller and the plurality of circuit elements 270. Therefore, the timing controller and the plurality of circuit elements 270, and the LCD device can be protected from ESD.

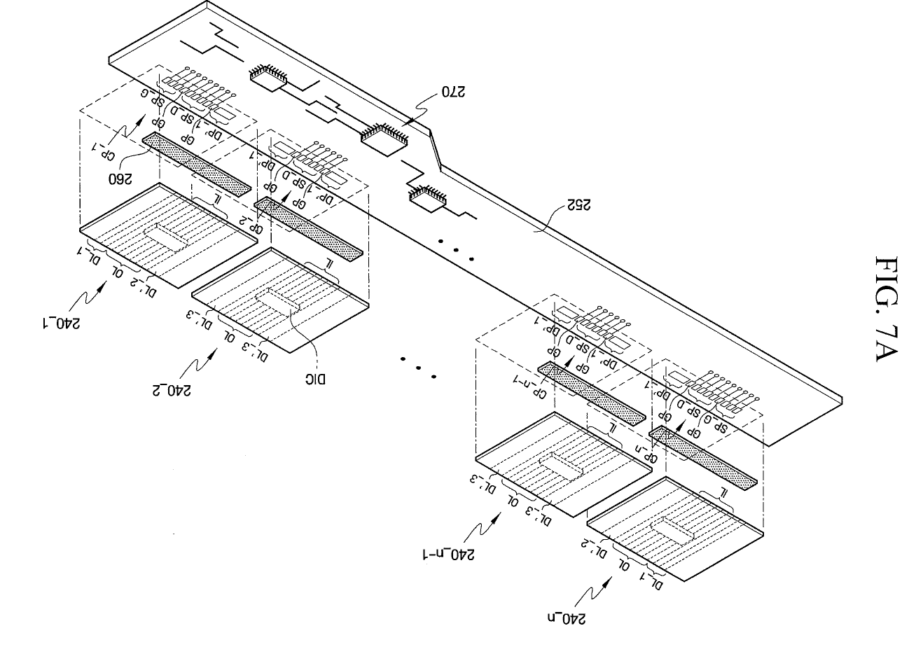

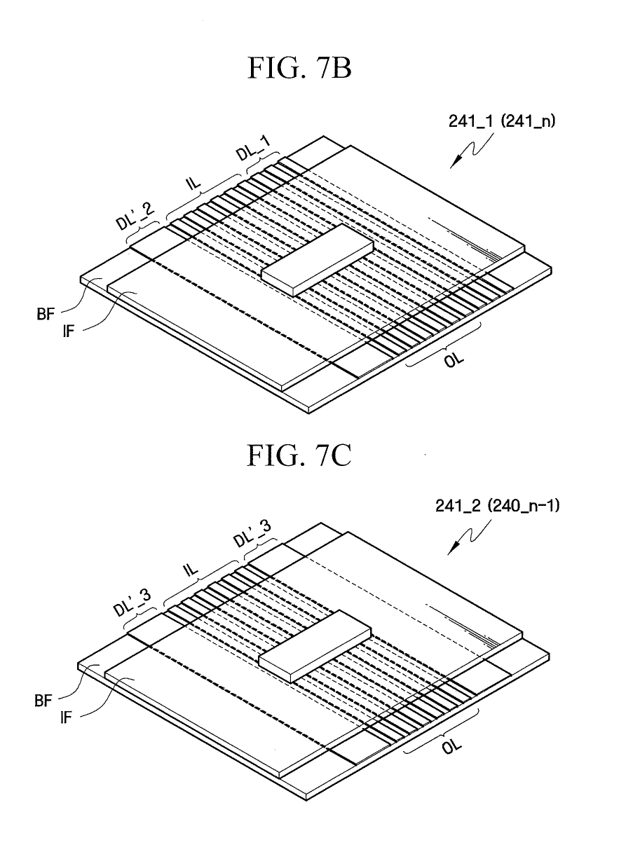

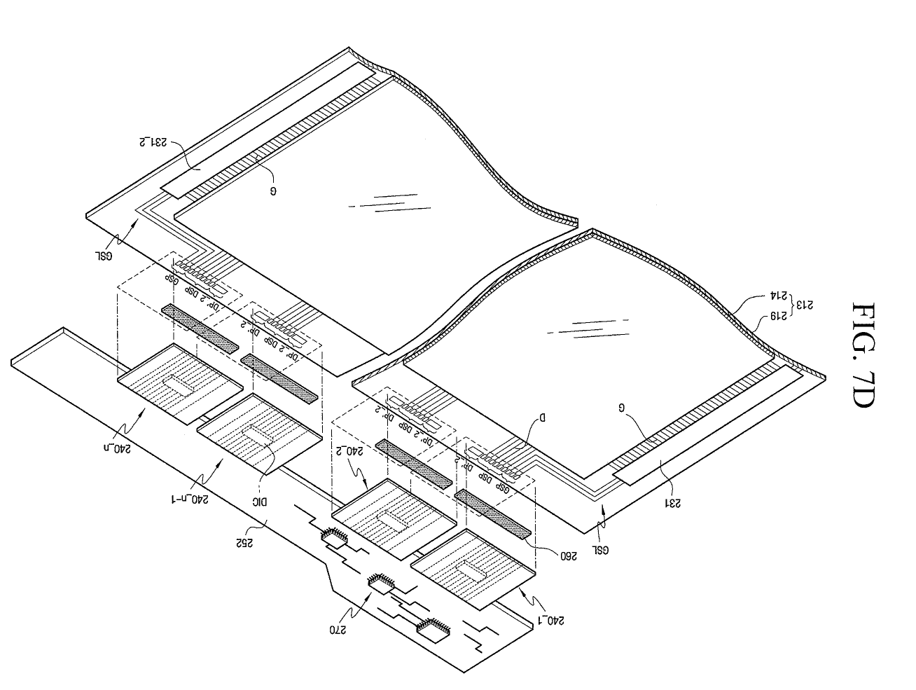

FIG. 7A is a perspective view illustrating a circuit board according to an exemplary embodiment of the present invention. FIG. 7B is a perspective view illustrating first to n-th data driving semiconductor chip packages of FIG. 7A. FIG. 7C is a perspective view illustrating second to (n−1)th data driving semiconductor chip packages of FIG. 7A. FIG. 7D is a perspective view illustrating a liquid crystal panel according to an exemplary embodiment of the present invention. Parts having the same functions as those shown in FIGS. 2B, 2C, 6A, and 6B are represented by the same reference numerals, and the detailed descriptions thereof will be omitted for convenience of explanation.

Referring to FIG. 7A, the circuit board 252 includes first to n-th connection portions CP_1 to CP_n. First dummy pads DP′_1 of each of the connection portions CP_1 to CP_n are formed wider compared with the above embodiments.

Dummy lines DL′_2 and DL′_3 of each of the data driving semiconductor chip packages 240_1 to 240_n are formed wider compared with the above embodiments, as shown in FIGS. 7B and 7C.

Second dummy pads DP′_2 on the liquid crystal panel 213 are formed wider compared with the above embodiments, as shown in FIG. 7D.

The first dummy pads DP′_1 of the circuit board 252 are electrically insulated from the ground pad GP and the signal output pads SP_D and SP_D. Thus, when ESD flows into the first dummy pad DP′_1 along the liquid crystal panel 213, the second dummy pads DP′_2, and the dummy lines DL′_2 and DL′_3, ESD is not transferred to the timing controller and the plurality of circuit elements 270. Therefore, tie timing controller and the plurality of circuit elements 270, and the LCD device can be protected from ESD.

Since the first dummy pads DP′_1, the dummy lines DL′_2 and DL′_3, and the second dummy pads DP′_2 and DP′_3 are formed wider, and the adhesion areas are widened, adhesive strength between the liquid crystal panel 213 and the data driving semiconductor chip packages 240_1 to 240_n and adhesive strength between the data driving semiconductor chip packages 240_1 to 240_n and the circuit board 252 are increased.

As described above, according to embodiments of the present invention, the display device having the circuit board, the circuit elements on the circuit board can be protected from ESD, and thus the display device can be protected.

Although the illustrative embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A circuit board comprising:
first to n-th connection portions to supply a plurality of signals, wherein each of the connection portions comprises:
a ground pad,
signal output pads to output the signals; and
conductive dummy pads insulated from the ground pad and the signal output pads.

2. The circuit board of claim 1, wherein the plurality of signals include gate driving signals and data driving signals.

3. The circuit board of claim 2, wherein the signal output pads of the first connection portion comprise gate signal output pads to output the gate driving signals and data signal output pads to output the data driving signals.

4. The circuit board of claim 2, wherein the signal output pads of each of the second to n-th connection portions output the data driving signals.

5. The circuit board of claim 2, wherein the signal output pads of each of the first connection portion and the n-th connection portion comprise gate signal output pads to output the gate driving signals, and data signal output pads to output the data driving signal.

6. The circuit board of claim 5, wherein the signal output pads of each of the second to (n−1)th connection portions output the data driving signals.

7. A display device comprising:
a circuit board to output a plurality of signals through first to n-th connection portions, each of the connection portions including a ground pad, signal output pads outputting the signals, and conductive first dummy pads insulated from the ground pad and the signal output pads;
first to n-th data driving semiconductor chip packages connected to the first to n-th connection portions;
a plurality of gate driving semiconductor chip packages connected to the circuit board; and
a liquid crystal panel including a plurality of data lines electrically connected to the first to n-th data driving semiconductor chip packages, a plurality of gate lines connected to the plurality of gate driving semiconductor chip packages, and second dummy pads connected to the first to n-th data driving semiconductor chip packages.

8. The display device of claim 7, wherein the first data driving semiconductor chip package comprises:
an insulating base film;
a data driving IC;
data signal input lines connecting the ground pad and a part of the signal output pads of the first connection portion to the data driving IC;
gate signal output lines connecting the remaining signal output pads to the plurality of gate driving semiconductor chip packages;
data signal output lines connecting the data driving IC to the plurality of data lines; and
dummy lines connecting the first dummy pads of the first connection portion to the second dummy pads of the liquid crystal panel.

9. The display device of claim 7, wherein each of second to n-th data driving semiconductor chip packages comprises:
an insulating base film;
a data driving IC;
data signal input lines connecting the ground pad and the signal output pads of each of the second to n-th connection portions to the data driving IC;
data signal output lines connecting the data driving IC to the plurality of data lines; and
dummy lines connecting the first dummy pads of each of second to n-th connection portions to the second dummy pads of the liquid crystal panel.

10. The display device of claim 9, wherein the liquid crystal panel further comprises gate signal transmission lines connecting the gate signal output lines to the plurality of gate driving semiconductor chip packages.

11. The display device of claim 7, wherein each of the first data driving semiconductor chip package and the n-th data driving semiconductor chip package comprises:
an insulating base film;
a data driving IC;
data signal input lines connecting the ground pad and a part of the signal output pads of each of the first connection portion and the n-th connection portion to the data driving IC;
data signal output lines connecting the data driving IC to the plurality of data lines;
gate signal output lines connecting the remaining signal output pads of each of the first connection portion and the n-th connection portion, and the plurality of gate driving semiconductor chip packages; and
dummy lines connecting the first dummy pads of each of first connection portion and the n-th connection portion to the second dummy pads of the liquid crystal panel.

12. The display device of claim 11, wherein each of the second to (n−1)th data driving semiconductor chip packages comprises:
an insulating base film;
a data driving IC;
data signal input lines connecting the ground pad and the signal output pads of each of the second to (n−1)th connection portions to the data driving IC;
data signal output lines connecting the data driving IC to the plurality of data lines; and
dummy lines connecting the first dummy pads of each of second to (n−1)th connection portions to the second dummy pads of the liquid crystal panel.

13. The display device of claim 12, wherein the plurality of gate driving semiconductor chip packages are divided into a group of first gate driving semiconductor chip packages and a group of second gate driving semiconductor chip packages, and the group of first gate driving semiconductor chip packages is connected to one side of the liquid crystal panel, and the group of second gate driving semiconductor chip packages is connected to the other side of the liquid crystal panel.

14. The display device of 13, wherein the group of first gate driving semiconductor chip packages is connected to the gate signal output lines of the first data driving semiconductor chip package, and the group of second gate driving semiconductor chip packages is connected to the gate signal output lines of the n-th data driving semiconductor chip package.

15. The display device of claim 14, wherein the liquid crystal panel further comprises:
first gate signal transmission lines connecting the gate signal output lines of the first data driving semiconductor chip package to the group of first gate driving semiconductor chip packages; and
second gate signal transmission lines connecting the gate signal output lines of the n-th data driving semiconductor chip package to the group of second gate driving semiconductor chip packages.

16. The display device of claim 7, wherein the second dummy pads are insulated from the plurality of data lines.

17. The display device of claim 7, wherein the first to n-th data driving semiconductor chip packages are adhered to the first to n-th connection portions through an anisotropic conductive film (ACF).

18. The display device of claim 7, wherein the width of each of the first dummy pads is wider than the width of the ground pad and the width of each of the signal output pads.
